(19) United States
(12) Patent Application Publication
(10) Pub. No.: US 2024/0132341 A1
(43) Pub. Date: Apr. 25, 2024

(54) MEMS RESONANT SENSOR ADAPTED TO GENERATE A PULSE OUTPUT SIGNAL

(71) Applicant: COMMISSARIAT A L’ENERGIE ATOMIQUE ET AUX ENERGIES ALTERNATIVES, Paris (FR)

(72) Inventors: Emmanuel HARDY, GRENOBLE (FR); Bruno FAIN, GRENOBLE (FR); Elisa VIANELLO, GRENOBLE (FR)

(21) Appl. No.: 18/381,027

(22) Filed: Oct. 16, 2023

(30) Foreign Application Priority Data
Oct. 19, 2022 (FR) 2210836

(51) Int. Cl. B81B 7/02; G01P 15/125

(52) U.S. Cl. CPC B81B 7/02; G01P 15/125; B81B 2201/0271

(57) ABSTRACT

A MEMS resonant sensor adapted to generate a pulse output signal from a signal of interest, the signal of interest being a signal having a frequency oscillating around a carrier frequency, the MEMS sensor comprising at least one processing channel for processing the signal of interest, each processing channel comprising: a demodulation unit for demodulating the signal of interest in order to form a demodulated signal, the demodulation unit comprising a frequency mixer between the signal of interest and a reference signal, the demodulated signal having a low-frequency component and a high-frequency component; a filtration unit for filtering the demodulated signal in order to form a filtered signal, the filtration unit being adapted to allow through the low-frequency component of the demodulated signal; a comparison unit for comparing the filtered signal with a fixed threshold signal in order to form a comparison signal, the comparison signal comprising rising edges and falling edges; a detection unit for detecting rising edges, each rising edge corresponding to a pulse of the output signal.

### CROSS-REFERENCE TO RELATED APPLICATION

This application claims priority to foreign French patent application No. FR 2210836, filed on Oct. 20, 2022, the disclosure of which is incorporated by reference in its entirety.

### FIELD OF THE INVENTION

The present invention relates to MEMS (Micro-electromechanical Systems) resonant sensors. These MEMS resonant sensors form a large family of MEMS sensors: mass sensors, gas sensors, accelerometers, etc. These sensors operate around a resonance frequency, which depends on the parameter of interest. In the case of a gas sensor, the resonance frequency directly depends on the mass of the movable structure, which in turn depends on the species adsorbed on the surface and therefore on the gas concentration. In the case of a resonant accelerometer, the frequency of a resonant movable structure depends on the acceleration via the quasi-static displacement of a mass subjected to inertial forces. For all these sensors, the mechanical signal of interest is an AC signal, even when the signal to be measured is a DC signal (constant acceleration, or constant gas concentration).

The signal originating from the MEMS is processed by interface electronics, referred to hereafter as “analogue front-end” (AFE). At the output of the AFE, the signal can be processed in various ways, by on-board electronics, or by remote processing units, in real time or off-line, so as to deliver the relevant information.

The invention relates to all MEMS resonant sensors. It is particularly relevant when signal processing is carried out in real time by on-board neuromorphic type processing in real time, i.e., processing which imitates the operation of neurons.

### BACKGROUND

In recent years, sensors have proliferated in many fields (IoT, automotive, etc.). The data originating from these sensors is increasingly processed using “machine learning” type processing, which allows relevant information to be extracted from a large amount of data. This processing can be carried out on conventional digital units, i.e., microprocessors with transistors that reproduce the structure of a neural network, or even, advantageously, with circuits with a hardware structure that closely imitates the operation of a neural network. This type of circuit has several advantages:
reduction in consumption by several orders of magnitude;
no intermediate storage of generated data;
no data transfer to an external control unit;
real-time processing.

This type of circuit is based on spiking neural networks (SNNs). However, optimal coupling with the sensors generating the pulses is rarely achieved. A “spike-based sensor” is defined herein as any type of sensor including added electronics that process information as a sequence of events or pulses without passing through a conventional analogue-to-digital converter. In the article entitled, “Towards spike-based machine intelligence with neuromorphic computing” by K. Roy, A. Jaiswal, and P. Panda, Nature, Vol. 575, No. 7784, pages 607-617, November 2019, doi: 10.1038/s41586-019-1677-2, a prior art of integrated circuit neuromorphic processing is described. These “spike-based sensors” are used for vision, as indicated in the document entitled, “A Spike-Based Neuromorphic Architecture of Stereo Vision” by N. Risi, A. Aimar, E. Donati, S. Solinas, and G. Indiveri in Frontiers in Neurorobotics, Vol. 14, 2020, Accessed: Jul. 7, 2022. [Online]. Available: https://www.frontiersin.org/articles/10.3389/fnbot.2020.568283. These “spike-based sensors” are also used for audio, as indicated in the document entitled, “AER EAR: a matched silicon cochlea pair with address event representation interface” by A. van Schaik and S.-C. Liu in 2005 IEEE International Symposium on Circuits and Systems (ISCAS), May 2005, pages 4213-4216 Vol. 5. doi: 10.1109/ISCAS.2005.1465560.

With respect to odour sensors, the document entitled, “Rapid online learning and robust recall in a neuromorphic olfactory circuit” by N. Imam and T. A. Cleland in Nature Machine Intelligence, Vol. 2, No. 3, pages 181-191, March 2020, doi: 10.1038/s42256-020-0159-4, proposes a real-time pulse conversion of the output voltage after digital conversion of a “chemo-sensor” measuring changes in conductivity. This digital conversion step makes the system sub-optimal, but it allows pulse conversion to be carried out easily using off-the-shelf electronic components.

Numerous studies exist on resonant sensors and how to read the resonance frequency with the desired sampling and resolution.

In particular, approaches involving a PLL (Phase-Locked Loop) can be cited. In this type of architecture, the resonant structure is excited at its resonance frequency via a phase-locked loop. The excitation frequency therefore reproduces a variable of interest, as explained in the document entitled, “Frequency-addressed NEMS arrays for mass and gas sensing applications” by E. Sage et al., in 2013 Transducers & Eurosensors XXVII: The 17th International Conference on Solid-State Sensors, Actuators and Microsystems (TRANSDUCERS & EUROSENSORS XXVII), June 2013, pages 665-668. doi: 10.1109/Transducers.2013.6626854.

Other approaches involve a self-oscillation loop comprising the MEMS and amplification electronics, as indicated in the document entitled, “Improved Interface Circuits for CMUT Chemical Sensors” by Q. Stedman, J. D. Fox, and B. T. Khuri-Yakub in 2019 IEEE International Ultrasonics Symposium (IUS), October 2019, pages 989-992. doi: 10.1109/ULTSYM.2019.8926206. With the correct dimensioning, this type of architecture naturally begins to oscillate at a frequency close to the resonance frequency. A second electronic stage fulfils the frequency counter function, which yields a digital output signal proportional to the self-oscillation frequency. A particular type of sensor is the electronic nose. This is a set of sensors, for example, “gravimetric” sensors, each with a particular chemical affinity towards the various gases that are likely to be measured. Thus, the response of each sensor to a given set of gases is specific. Processing the data originating from the various sensors allows the composition of the gas to be determined. This principle, which imitates the function of the human nose, is known as the electronic nose principle.

In the case of an electronic nose based on resonant gravimetric sensors (cMUT, SAW, NEMS, quartz microbalance, etc.), the signal from each sensor is a resonance or self-oscillation frequency.

Information processing therefore involves detecting the value of the resonance frequency for each sensor, then combining the various frequencies in order to extract information concerning the nature (and the amount) of the gas. This processing is carried out via a reference database. In the case of “machine learning” type processing, this database is used for learning, which will allow classification.

A requirement exists for proposing a generic architecture for MEMS resonant sensors adapted to deliver signals in the form of pulses.

### SUMMARY OF THE INVENTION

The present invention aims to at least partly address this requirement.

More specifically, the aim of the present invention is to cover a MEMS resonant sensor adapted to generate a pulse output signal from a signal of interest, said signal of interest being a square-wave signal having a frequency oscillating around a carrier frequency, said MEMS sensor comprising at least one processing channel for processing the signal of interest, each processing channel comprising:
a demodulation unit for demodulating the signal of interest in order to form a demodulated signal, said demodulation unit comprising a frequency mixer between said signal of interest and a reference signal, said demodulated signal having a low-frequency component and a high-frequency component;
a filtration unit for filtering the demodulated signal in order to form a filtered signal, the filtration unit being adapted to allow through the low-frequency component of the demodulated signal;
a comparison unit for comparing the filtered signal with a fixed threshold signal in order to form a comparison signal, said comparison signal comprising rising edges and falling edges;
a detection unit for detecting rising edges, each rising edge corresponding to a pulse of the output signal.

Thus, the invention allows a generic architecture to be acquired for MEMS resonant sensors whose carrier frequency, also called resonance frequency, is measured, so that these sensors are “spike-based sensors”, delivering signals in the form of pulses. In terms of electronics, there are numerous advantages, notably for integration. In addition, the binary nature of the signal makes it highly resistant to electromagnetic interference. Furthermore, the amount of pulses is proportional to the activity/strength of the signal. This allows reduced consumption when the signal is weak or absent. It is the MEMS resonant sensor, via its conditioning electronics, that is adapted to generate the pulse output signal.

In a particular embodiment, the sensor comprises a CMUT transducer adapted to generate the signal of interest from a variation in a studied physical feature.

In a particular embodiment, the studied physical feature from which the signal of interest is generated is selected from a group of physical features comprising at least:
a gas;
a mass;
an acceleration.

In a particular embodiment, the sensor comprises at least two processing channels, each processing channel having a specific CMUT transducer with a view to generating a pulse output signal specific to said processing channel.

In a particular embodiment, the output of each processing channel is coupled to a classifier, said classifier being adapted to classify the studied physical feature.

In a particular embodiment, the classifier is adapted to process digital data and in that each processing channel comprises a conversion unit for converting pulses to digital data.

In a particular embodiment, the classifier is a pulse neural network.

The use of such a classifier is particularly relevant in the case of matrix or multi-channel sensors, all of which are parallel inputs for the neuromorphic circuit.

In a particular embodiment, the sensor comprises a transition detector, said transition detector being adapted to set all or some of the processing channels to standby if the studied physical feature does not vary over a certain period, said transition detector being adapted to take all or some of the processing channels out of standby if the studied physical feature varies rapidly.

In a particular embodiment, the MEMS sensor comprises a calibration unit for calibrating the reference signal in the demodulation unit.

### BRIEF DESCRIPTION OF THE DRAWINGS

The present invention will be better understood upon reading the detailed description of embodiments taken by way of non-limiting examples and illustrated by the appended drawings, in which:

FIG. 1 illustrates a MEMS resonant sensor according to a first embodiment of the invention;

FIG. 2 illustrates a MEMS resonant sensor according to a second embodiment of the invention comprising a plurality of processing channels;

FIG. 3 illustrates the principle of converting the pulses generated by the MEMS sensors of FIGS. 1 and 2 into a digital signal;

FIG. 4 illustrates a MEMS resonant sensor according to a third embodiment of the invention;

FIG. 5 illustrates the principle of detecting transitions on each processing channel of the MEMS resonant sensor of FIG. 2;

FIG. 6 illustrates a MEMS resonant sensor according to a fourth embodiment of the invention.

### DETAILED DESCRIPTION

The invention is not limited to the embodiments and alternative embodiments that are described and other embodiments and alternative embodiments will become clearly apparent to a person skilled in the art.

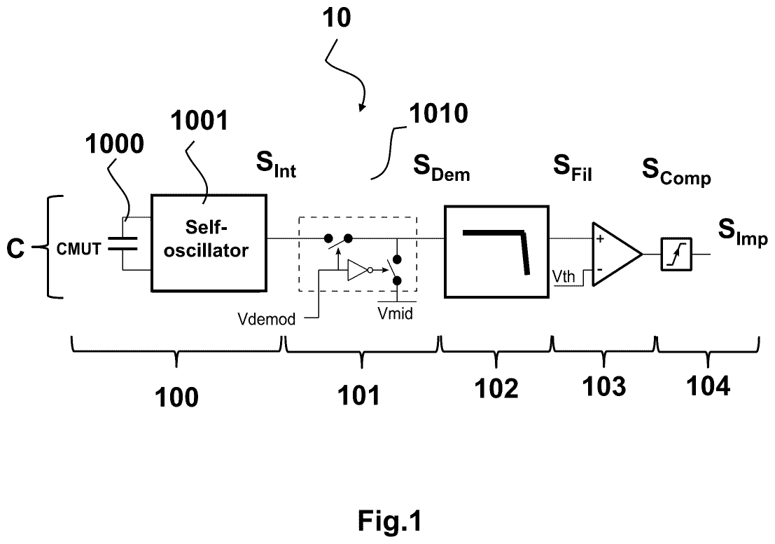

FIG. 1 illustrates a MEMS resonant sensor 10 according to a first embodiment of the invention. In this embodiment, the MEMS resonant sensor comprises:
an assembly 100;
a demodulation unit 101;
a filtration unit 102;
a comparison unit 103;
a detection unit 104.

The assembly 100 is adapted to generate a signal of interest S_{Int} from a variation in a studied physical feature. Such a studied physical feature is, for example, a gas, a mass or an acceleration. It should be noted that the signal of interest S_{Int} in this case is a periodic signal, for example, a square-wave signal. A square-wave signal is understood to mean a signal that regularly and instantaneously alternates between two levels.

More specifically, the assembly 100 comprises a CMUT sensor 1000 and a self-oscillator 1001. These self-oscillation electronics are designed so that the MEMS spontaneously oscillates when the electronics are powered, notably by a DC voltage. The oscillation frequency of a resonant MEMS is dictated by its mechanical structure, which is designed to achieve the desired performance. For example, in the case of a cMUT transducer, this frequency can range between 10 and 50 MHz for a bandwidth of 100 kHz.

The demodulation unit 101 is adapted to demodulate the signal of interest S_{Int} in order to form a demodulated analogue signal S_{Dem}. This demodulation unit 101 comprises a frequency mixer 1010 between the signal of interest S_{Int} and a reference signal V_{demod}. This demodulated analogue signal S_{Dem} has a low-frequency component and a high-frequency component. Thus, the role of the demodulation electronics is to bring the signal to a low frequency between 0 Hz and the value of its bandwidth, 100 kHz in this example. In the absence of a physical signal of interest, for example, if there is no acceleration or no gas, the demodulation electronics bring the signal to a zero frequency. This allows a DC signal to be available in the absence of a physical signal of interest, which allows the consumption of some subsequent units to be limited.

The processing carried out by the demodulation unit 101 is based on the principle of frequency mixing between a signal of interest sin(w₀+dw)t, called S_{Int}, and a reference signal sin wot, called (V_{demod}). This is the heterodyne method, based on the multiplication of several frequencies illustrated by the following equation:

sin(w₀t)*sin(w₀+dw)t=½*cos(dwt)−½*cos(2w₀+dw)t,

where w₀ corresponds to a pulsation and dw corresponds to a variation in pulsation.

Frequency mixing involves switches in this case. Using on/off switches on the signal of interest S_{Int} is equivalent to mixing it with a square-wave signal.

The filtration unit 102 for filtering the demodulated signal S_{Dem} is adapted to form a filtered analogue signal S_{Fil}. It thus allows the low-frequency component of the demodulated analogue signal S_{Dem} to pass through. This filtration unit 102 is also called “Low Pass Filter”.

The comparison unit 103 is adapted to compare the filtered signal S_{Fil} with a fixed threshold signal Vth in order to form a comparison signal S_{comp}. This comparison signal S_{comp} comprises rising edges and falling edges. This comparison unit 103 is also called “comparator”.

The detection unit 104 is adapted to detect rising edges. Each rising edge will correspond to a pulse S_{Imp} of the output signal. This detection unit 104 is also called “Rising Edge”.

The CMUT transducer 100, the demodulation unit 101, the filtration unit 102, the comparison unit 103, the detection unit 104 form a processing channel C or path of the MEMS sensor 10.

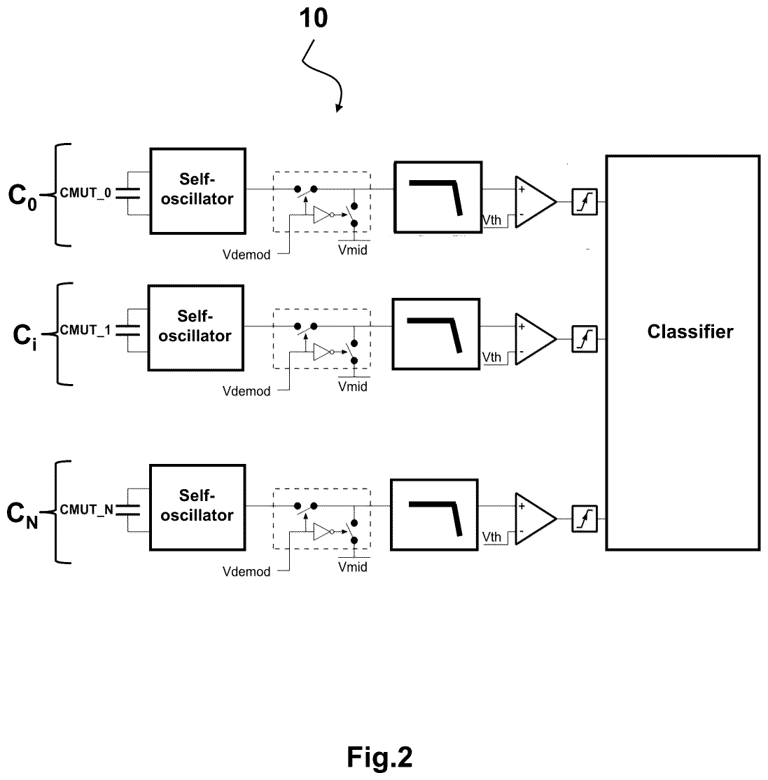

FIG. 2 illustrates a MEMS resonant sensor according to a second embodiment of the invention comprising a plurality of processing channels C₀, . . . , Cᵢ, . . . , C_{N}. Such a sensor is called cMUT or multi-channel cMUT sensor. Each processing channel C₀, . . . , Cᵢ, . . . , C_{N} comprises a CMUT transducer, a demodulation unit, a filtration unit, a comparison unit and a detection unit. The output of all the processing channels C₀, . . . , Cᵢ, . . . , C_{N} is coupled to the same classifier, for example, a spiking neural network SNN type classifier. Such a classifier is suitable for classifying the studied physical feature.

It should be noted that the coupling between a cMUT and the SNN is not obvious because the expertise is provided by different participants from different communities.

It also should be noted that in the case of a resonant accelerometer, it is possible to design a single-channel system that delivers temporal information in the form of pulses, which is processed in order to analyse the type of movements. By way of a comparison, data fusion algorithms within a smartphone can be used to determine whether the smartphone holder is walking, on a train or in a car.

A system made up of a plurality of resonant accelerometers measuring acceleration along 3 axes also can be proposed.

In general, any combination with other types of resonant sensors (gyrometers, pressure sensors, etc.) can result in the creation of a “spike-based sensor” delivering relevant signals to the SNN.

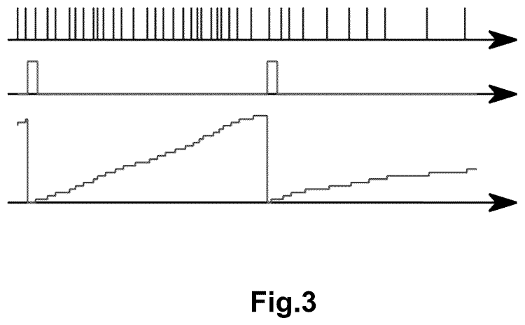

If the signals are not used directly by an SNN, an electronic unit allows the pulse signal to be converted into a digital signal containing information concerning the oscillation frequency of the MEMS. FIG. 3 shows the principle of such a unit with a series of asynchronous pulses as input (upper line in the figure), an asynchronous pulse counter (middle line) and a reference signal (lower line), which sends a counter reset signal with a fixed frequency, allowing a pulse density to be measured.

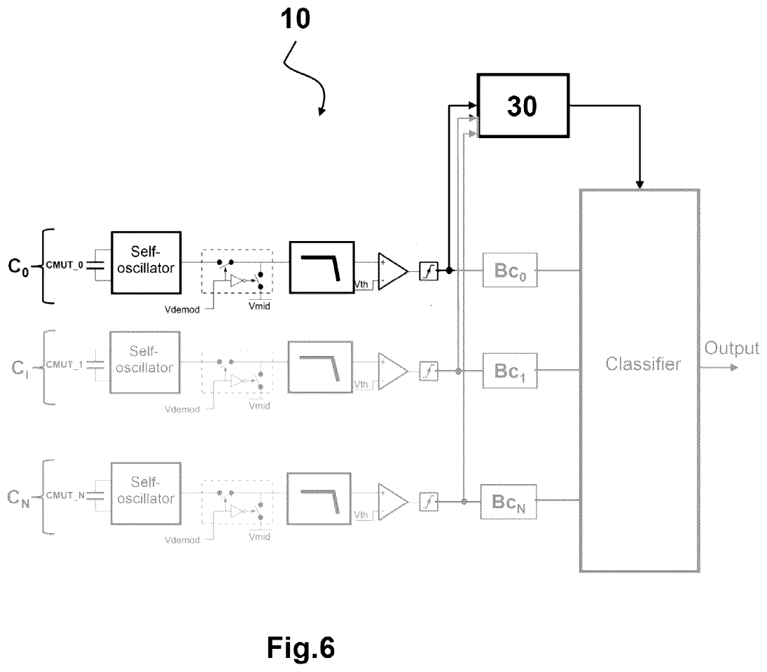

The electronic unit for converting the signal is illustrated in FIG. 6 and is positioned at the output of a detection unit. In this figure, each processing channel C₀, . . . , Cᵢ, . . . C_{N} comprises a conversion unit Bc₀, . . . , Bcᵢ, . . . Bc_{N} for converting pulses into digital data. These conversion units Bc₀, . . . , Bcᵢ, . . . Bc_{N} are intended to supply a classification system that is not an SNN. In order for heterodyne demodulation to work optimally, with a pulse density equal to 0 when the CMUT resonates at its no-load frequency f₀=w₀/2π, the demodulation signal at the mixer input must have a frequency equal to this no-load frequency.

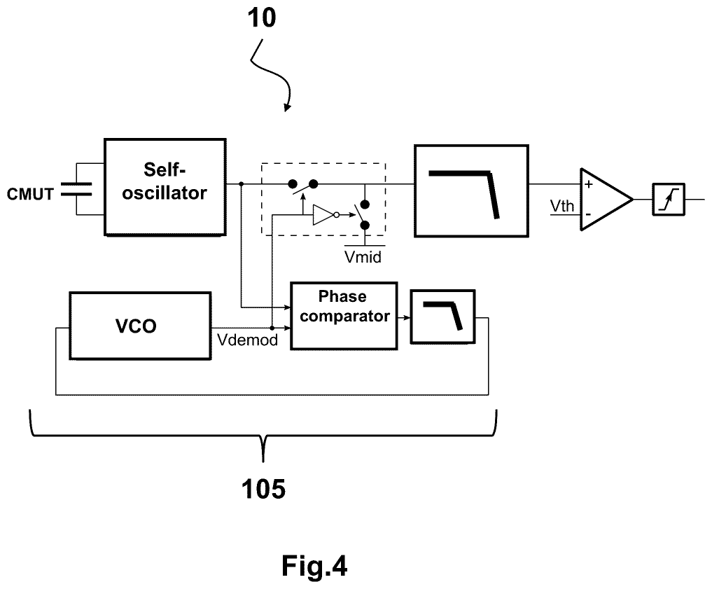

FIG. 4 shows a possible calibration circuit 105 where the CMUT resonates at w₀. The reference signal V_{demod} is generated by a frequency-controlled oscillator (VCO). Its voltage-to-phase transfer function is an integrator. The phase difference between V_{demod} and the output of the self-oscillator is determined using a phase comparator. A low-pass filter is added in order to stabilise the control voltage of the VCO.

During normal operation, the feedback loop of the calibration circuit is switched off and the calibrated voltage is maintained at the input of the VCO.

This circuit also can be used to compensate for drifts during operation using an appropriate algorithm, for example, minimum detection over a wide time window.

Some odour classifiers can operate only on stabilised sensor states. If this is the case, a transition detector can allow the classifier to be inhibited when the state of the sensors has not stabilised.

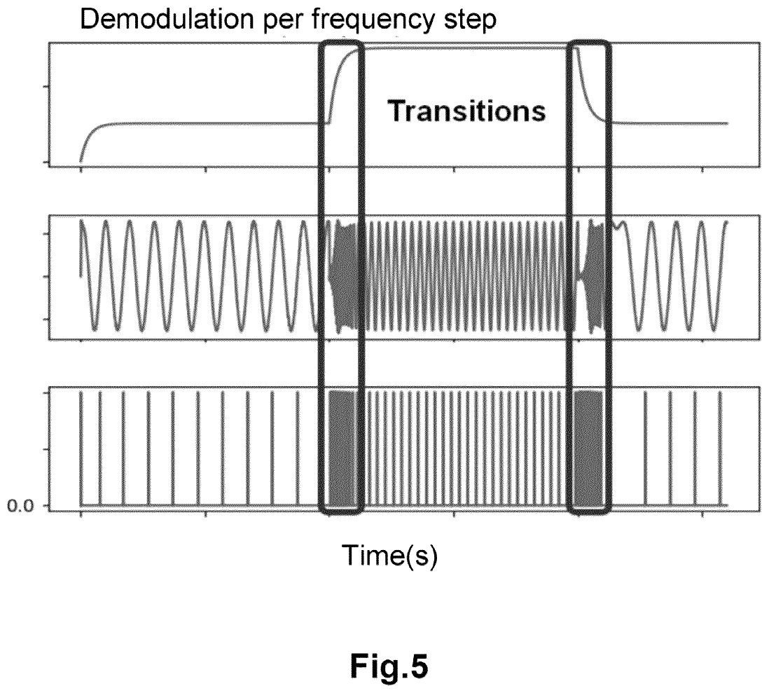

FIG. 5 shows that, during transitions, the demodulated signal becomes a high frequency signal. This is due to the fact that the frequency “step” contains all the frequencies that demodulate in the baseband. The top of the figure shows the modulation frequency varying over time, the middle of the figure shows the output of the low-pass filter after demodulation and the bottom of the figure shows the pulse train.

In FIG. 6, at least one transition detector 30 connected to each channel is added. This transition detector 30 can thus transmit a control message, called “inference_enable” message, to the classifier in order to notify said classifier whether or not the measurement is stabilised. These transitions can be detected using a frequency counter as in FIG. 3, or even using a “Leaky Integrate and Fire” neuron implemented in analogue or digital form. It should be noted that in FIG. 6 the processing channels Cᵢ to C_{N} are transparent relative to the processing channel C₀ so as to indicate that these channels Cᵢ to C_{N} are on standby.

By observing that the channels are correlated with each other, it is possible for the odour sensor to operate in a low-power mode with at least one channel switched on in order to detect the presence of a gas with the transition detector described above (see FIG. 6). When a gas is detected, the other channels are switched on in order to allow classification.

This architecture is obviously particularly relevant if the signal is processed by “machine learning”, notably when coupled with a neuromorphic pulse processing circuit. In particular, it applies to matrix or multi-channel sensors, all of which are parallel inputs for the neuromorphic circuit. The case of the electronic nose is the most interesting target case, since the very principle of the sensor is based on a classification, which is sometimes achieved with “machine learning”.

This invention falls within the scope of low-power systems, which implies particular architectures (no ADC, no frequency counter). However, the invention also applies to systems that are not low-power systems.

1. A MEMS resonant sensor adapted to generate a pulse output signal (S_{Imp}) from a signal of interest (S_{Int}), said signal of interest (S_{Int}) being a signal having a frequency oscillating around a carrier frequency, said MEMS sensor comprising at least one processing channel (C) for processing the signal of interest (S_{Int}), each processing channel (C) comprising:
a demodulation unit for demodulating the signal of interest (S_{Int}) in order to form a demodulated signal (S_{Dem}), said demodulation unit comprising a frequency mixer between said signal of interest (S_{Int}) and a reference signal (V_{demod}), said demodulated signal (S_{Dem}) having a low-frequency component and a high-frequency component;
a filtration unit for filtering the demodulated signal (S_{Dem}) in order to form a filtered signal (S_{Fil}), the filtration unit being adapted to allow through the low-frequency component of the demodulated signal (S_{Dem});
a comparison unit for comparing the filtered signal (S_{Fil}) with a fixed threshold signal (Vth) in order to form a comparison signal (S_{Comp}), said comparison signal (S_{Comp}) comprising rising edges and falling edges;
a detection unit for detecting rising edges, each rising edge corresponding to a pulse of the output signal (S_{Imp}).

2. The MEMS sensor according to claim 1, said sensor being adapted to generate the signal of interest (S_{Int}) from a variation in a studied physical feature.

3. The MEMS sensor according to claim 2, the studied physical feature from which the signal of interest (S_{Int}) is generated is selected from a group of physical features comprising at least:
a gas;
a mass;
an acceleration.

4. The MEMS sensor according to claim 1, said sensor comprising at least two processing channels (C₀, . . . Cᵢ, . . . C_{N}), each processing channel having a specific CMUT transducer with a view to generating a pulse output signal (S_{Imp0}, . . . , S_{Imp1}, . . . , S_{ImpN}) specific to said processing channel (C₀ . . . Cᵢ, . . . C_{N}).

5. The MEMS sensor according to claim 4, wherein the output of each processing channel (C₀, . . . , Cᵢ, . . . , C_{N}) is coupled to a classifier, said classifier being adapted to classify the studied physical feature.

6. The MEMS sensor according to claim 5, wherein the classifier is adapted to process digital data and in that each processing channel (C₀, . . . , Cᵢ, . . . , C_{N}) comprises a conversion unit (Bc₀, . . . , Bcᵢ, . . . , Bc_{N}) for converting pulses to digital data.

7. The MEMS sensor according to claim 5, wherein the classifier is a pulse neural network.

8. The MEMS sensor according to claim 5, wherein said sensor comprises a transition detector, said transition detector being adapted to set all or some of the processing channels (C₀, . . . , Cᵢ, . . . C_{N}) to standby if the studied physical feature does not vary over a certain period.

9. The MEMS sensor according to claim 1, wherein said MEMS sensor comprises a calibration unit for calibrating the reference signal (V_{demod}) in the demodulation unit.
